(19) United States
(12) Patent Application Publication
(10) Pub. No.: US 2026/0369243 A1
(43) Pub. Date: Nov. 19, 2026

(54) ELECTRONIC CIRCUIT AND DISPLAY DEVICE

(71) Applicant: SONY SEMICONDUCTOR SOLUTIONS CORPORATION, KANAGAWA (JP)

(72) Inventors: YU KAMADA, KANAGAWA (JP); HIDEO JINNOUCHI, KUMAMOTO (JP)

(21) Appl. No.: 19/477,907

(22) PCT Filed: Apr. 16, 2024
(86) PCT No.: PCT/JP2024/015132

§ 371 Date: Oct. 23, 2025

(30) Foreign Application Priority Data
May 15, 2023 (JP) 2023-080320

(51) Int. Cl. G09G 3/36

(52) U.S. Cl. CPC G09G 3/3648; G09G 2310/08; G09G 2320/0233; G09G 2320/0247; G09G 2320/043; G09G 2330/02

(57) ABSTRACT

The present disclosure provides an electronic circuit and a display device capable of preventing malfunction.

According to the present disclosure, there is provided an electronic circuit including: a first transistor; a second transistor; and a first switching element that electrically connects a gate of one of the first transistor and the second transistor, with a first wire, in a switchable manner, in which one end of the one of the first transistor and the second transistor is electrically connectable to a second wire different from the first wire, and a potential difference between the one end and another end of the first transistor is inverted between a case where the gate of the first transistor is electrically connected to the first wire and a case where the gate of the first transistor is not electrically connected to the first wire.

### TECHNICAL FIELD

The present disclosure relates to an electronic circuit and a display device.

### BACKGROUND ART

In recent years, display devices including liquid crystal cells have been required to have higher luminance, higher definition, and high reliability. In particular, transistors including non-single-crystal semiconductors are used to drive pixels and peripheral circuits, and therefore development is being carried out with the aim of improving not only device characteristics but also reliability.

The transistor is in an on state in most of the circuit operation period. In addition, depending on the time of the on state and the applied voltage, time degradation occurs that includes an increase in threshold voltage due to hot carrier injection and a decrease in current due to a decrease in mobility. Then, in a state where the degradation of the transistor is remarkable, malfunction occurs in the drive circuit and the peripheral circuit, and the image quality failure occurs.

### CITATION LIST

### Patent Document

Patent Document 1: Japanese Patent Application No. 2019-103537

### SUMMARY OF THE INVENTION

### Problems to be Solved by the Invention

Therefore, the present disclosure provides an electronic circuit and a display device capable of preventing malfunction.

### Solutions to Problems

In order to solve the problems described above, according to the present disclosure, there is provided an electronic circuit including:
a first transistor;
a second transistor; and
a first switching element that electrically connects a gate of one of the first transistor and the second transistor, with a first wire, in a switchable manner,
in which one end of the one of the first transistor and the second transistor is electrically connectable to a second wire different from the first wire, and
a potential difference between the one end and another end of the first transistor is inverted between a case where the gate of the first transistor is electrically connected to the first wire and a case where the gate of the first transistor is not electrically connected to the first wire.

A potential difference between the one end and another end of the second transistor may be inverted between a case where the gate of the first transistor is electrically connected to the first wire and a case where the gate of the first transistor is not electrically connected to the first wire.

A second switching element may be further provided that electrically connects the one end of either of the first transistor and the second transistor, with the second wire, in a switchable manner.

A first refresh potential may be applied to gates of the first transistor and the second transistor, and a second refresh potential different from the first refresh potential may be applied to one of the one ends of the first transistor and the second transistor.

There may be further provided:
a third switching element that switches between an applied state and a non-applied state of the first refresh potential to the gate of the first transistor;
a fourth switching element that switches between an applied state and a non-applied state of the first refresh potential to the gate of the second transistor;
a fifth switching element that switches between an applied state and a non-applied state of the second refresh potential to the one end of the first transistor; and
a sixth switching element that switches between an applied state and a non-applied state of the second refresh potential to the one end of the second transistor.

In a case where the gate of the first transistor is connected to the first wire, the third switching element and the fifth switching element may be brought into a disconnected state, and
in a case where the gate of the first transistor is not connected to the first wire, the third switching element and the fifth switching element may be brought into a connected state.

There may be further provided:
a third transistor connected in series to the first transistor; and
a fourth transistor connected in series to the second transistor.

In a case where the first transistor and the second transistor are n-type MOS transistors, the third transistor and the fourth transistor may be p-type MOS transistors.

In a case where the first transistor and the second transistor are n-type MOS transistors, the first refresh potential may be higher than the second refresh potential.

In a case where the first transistor and the second transistor are p-type MOS transistors, the third transistor and the fourth transistor may be n-type MOS transistors.

In a case where the first transistor and the second transistor are p-type MOS transistors, the first refresh potential may be lower than the second refresh potential.

The first wire may be alternately supplied with a high-level signal and a low-level signal.

The first refresh potential may be applied to a gate of the first transistor via a first resistor,
the first refresh potential may be applied to a gate of the second transistor via a second resistor,
the second refresh potential may be applied to the one end of the first transistor via a third resistor, and
the second refresh potential may be applied to the one end of the second transistor via a fourth resistor.

The first transistor and the second transistor may have equivalent input and output characteristics.

The third transistor and the fourth transistor may have equivalent input and output characteristics.

The second refresh potential may be generated by a charge pump circuit.

The first refresh potential may be generated by a first power supply having a variable potential.

The second refresh potential may be generated by a second power supply having a variable potential.

In order to solve the problems described above, according to the present disclosure, there is provided a display device including:
a plurality of scanning lines extending in a row direction, a plurality of signal lines extending in a column direction, and pixel array units each provided at a corresponding one of points where the scanning lines and the signal lines intersect with each other, the pixel array units each including a plurality of pixels;
a driver that causes each of the pixel array units to generate image light based on a video signal; and
a controller that executes control of drive in the driver,
in which the driver includes a vertical drive circuit connected to the plurality of scanning lines and a horizontal drive circuit connected to the plurality of signal lines,
the controller includes an electronic circuit that generates a vertical clock signal and supplies the vertical clock signal to the vertical drive circuit,
the electronic circuit includes:
a first transistor;
a second transistor; and
a first switching element that electrically connects a gate of one of the first transistor and the second transistor, with a first wire through which a clock signal is transmitted, in a switchable manner,
one end of the one of the first transistor and the second transistor is electrically connectable to a second wire that transmits the vertical clock signal, and
a potential difference between the one end and another end of the first transistor is inverted between a case where the gate of the first transistor is electrically connected to the first wire and a case where the gate of the first transistor is not electrically connected to the first wire.

Each of the pixels may include a liquid crystal cell, a pixel transistor that samples a voltage of a corresponding one of the signal lines based on a signal input from a corresponding one of the scanning lines and writes the voltage in the liquid crystal cell, and a capacitive element connected in parallel to the liquid crystal cell.

### BRIEF DESCRIPTION OF DRAWINGS

FIG. 1 is a diagram illustrating a schematic configuration of a display device according to a first embodiment.

FIG. 2 is a diagram illustrating a configuration example of an electronic circuit that generates a vertical clock signal.

FIG. 3 is a diagram illustrating an example of control signals input to a first switching element and a second switching element.

FIG. 4 is a diagram schematically illustrating a state of a first transistor in which a clock signal is in a low-level period.

FIG. 5 is a diagram schematically illustrating CHE of a first transistor in which a clock signal is in a low-level period.

FIG. 6 is a diagram illustrating a configuration example of an electronic circuit according to a second embodiment.

FIG. 7 is a diagram illustrating a configuration example of an electronic circuit electrically connected to an inverter circuit side.

FIG. 8 is a diagram illustrating a configuration example of an electronic circuit according to a third embodiment.

FIG. 9 is a diagram illustrating a configuration example of a charge pump circuit.

FIG. 10 is a diagram illustrating a configuration example of an electronic circuit according to a third embodiment.

### MODE FOR CARRYING OUT THE INVENTION

Hereinafter, embodiments of a light receiving device and a ranging system will be described with reference to the drawings. In the following, main components of the light receiving device and the ranging system will be described, but the light emitting device and the ranging system may have components and functions that are not illustrated or described. The following description is not intended to exclude components and functions that are not illustrated or described.

### First Embodiment

### Configuration

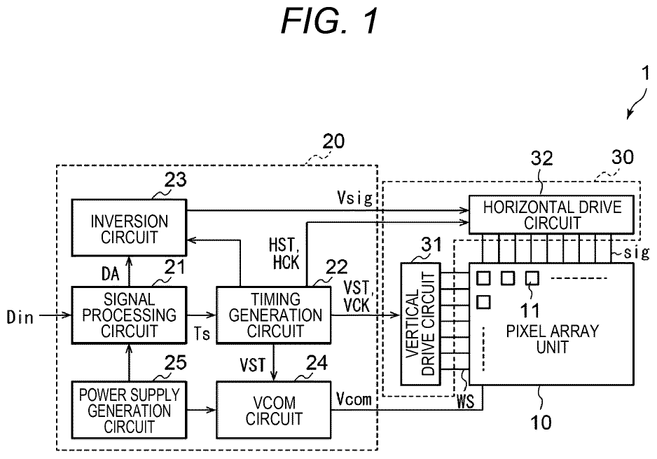

FIG. 1 is a diagram illustrating a schematic configuration of a display device 1 according to a first embodiment of the present disclosure. The display device 1 is applicable as a light valve of a three-plate projector (projection display device). The display device 1 includes, for example, a pixel array unit 10, a controller 20, and a liquid crystal driver 30. The pixel array unit 10 may be a transmissive type or a reflective type. Note that, in a case where the pixel array unit 10 is a transmissive type, the display device 1 may include a light source (not illustrated) behind the pixel array unit 10 as necessary. The display device 1 corresponds to a specific example of a “display device” of the present disclosure. The controller 20 corresponds to a specific example of a “control circuit” of the present disclosure.

### Pixel Array Unit 10

The pixel array unit 10 has, for example, a transmittance characteristic or a reflectance characteristic of normally black. Here, the term “normally black” refers to an optical characteristic in which transmittance or reflectance is minimized when no voltage is applied and black display is obtained. Note that the pixel array unit 10 may have, for example, a transmittance characteristic or a reflectance characteristic of normally white. Here, the term “normally white” refers to an optical characteristic in which transmittance or reflectance is maximized and white display is obtained when no voltage is applied. The pixel array unit 10 generates image light by electrically changing a polarization state of light by voltage application.

The pixel array unit 10 includes a plurality of scanning lines WS extending in the row direction, a plurality of signal lines Sig extending in the column direction, and a plurality of pixels 11 each provided at a corresponding one of points where the scanning lines WS and the signal lines Sig intersect each other. Each pixel 11 includes, for example, a liquid crystal cell, a pixel transistor that samples a voltage of the signal line Sig based on a signal input from the scanning line WS and writes the voltage in the liquid crystal cell, and a capacitive element connected in parallel to the liquid crystal cell.

### Controller 20

The controller 20 controls the liquid crystal driver 30 to drive each pixel 11, for example, with an active matrix drive by a field inversion drive method.

The controller 20 includes a signal processing circuit 21, a timing generation circuit 22, an inversion circuit 23, a VCOM circuit 24, and a power supply generation circuit 25.

For example, the signal processing circuit 21 converts a digital video signal Din input from the outside into an analog video signal DA for the pixel array unit 10, and outputs the converted video signal DA to the inversion circuit 23. Moreover, the signal processing circuit 21 separates a synchronization signal Ts from the video signal Din, for example, and outputs the separated synchronization signal Ts to the timing generation circuit 22. The timing generation circuit 22 forms, for example, a horizontal start signal HST and a horizontal clock signal HCK synchronized with the synchronization signal Ts, and outputs the signals to the horizontal drive circuit 32. The timing generation circuit 22 further forms, for example, a vertical start signal VST and a vertical clock signal VCK synchronized with the synchronization signal Ts, and outputs the signals to the vertical drive circuit 31. The timing generation circuit 22 further forms, for example, an inversion control pulse synchronized with the synchronization signal Ts and outputs the pulse to the inversion circuit 23. The timing generation circuit 22 further forms, for example, a vertical clock signal VCK synchronized with the synchronization signal Ts and outputs the signal to the VCOM circuit 24. The inversion circuit 23 performs a polarity inversion operation in accordance with the inversion control pulse. The inversion circuit 23 forms signal voltage Vsig whose polarity is inverted from video signal DA every one field period. The inversion circuit 23 outputs formed signal voltage Vsig to horizontal drive circuit 32. The power supply generation circuit 25 generates a voltage necessary for the signal processing circuit 21, the VCOM circuit 24, and the like, and supplies the voltage to the signal processing circuit 21 and the VCOM circuit 24.

### Liquid Crystal Driver 30

The liquid crystal driver 30 drives each pixel 11 with an active matrix drive to generate image light from the pixel array unit 10, based on a video signal input from the outside. The liquid crystal driver 30 includes a vertical drive circuit 31 connected to the plurality of scanning lines WS and a horizontal drive circuit 32 connected to the plurality of signal lines Sig.

### Configuration of Electronic Circuit 220

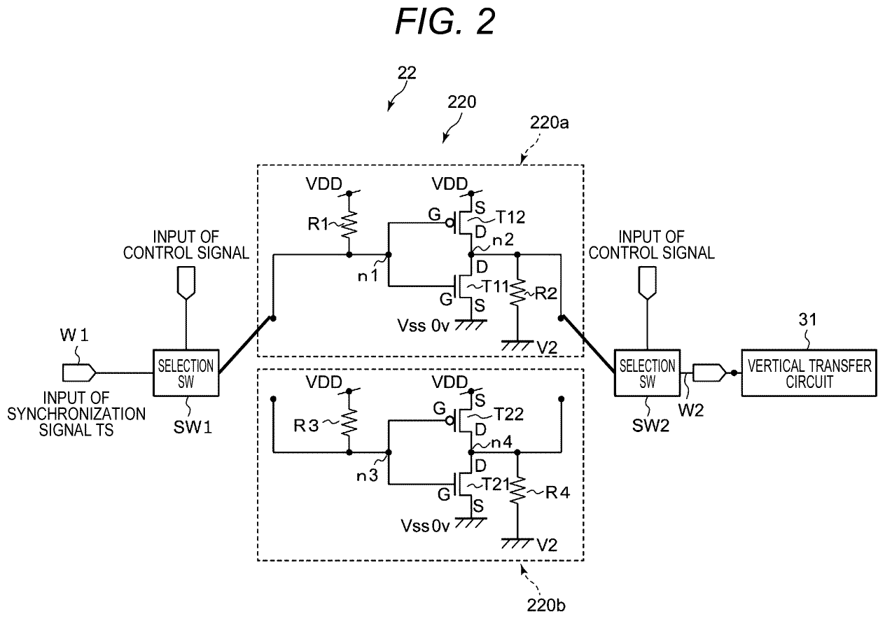

FIG. 2 is a diagram illustrating a configuration example of an electronic circuit 220 that generates the vertical clock signal VCK in the timing generation circuit 22. As illustrated in FIG. 2, the electronic circuit 220 includes a first switching element SW1, a second switching element SW2, an inverter circuit 220a, and an inverter circuit 220b. The inverter circuit 220a and the inverter circuit 220b have an equivalent configuration.

The first switching element SW1 electrically connects the first wire W1 with either of the inverter circuit 220a and the inverter circuit 220b in a switchable manner in accordance with a control signal. The first switching element SW1 outputs a synchronization signal TS to one of the inverter circuit 220a and the inverter circuit 220b that is electrically connected to the first switching element SW1. The synchronization signal TS is a clock signal and is a time-series high-level pulse signal.

The second switching element SW2 electrically connects the second wire W2 with either of the inverter circuit 220a and the inverter circuit 220b in a switchable manner in accordance with a control signal. The first switching element SW1 and the second switching element SW2 electrically connect the first wire W1 and the second wire W2 to the inverter circuit 220a side, for example, in a case of a high-level signal (High). Contrarily, the first switching element SW1 and the second switching element SW2 electrically disconnect the first wire W1 and the second wire W2 from the inverter circuit 220b, for example, in a case of a high-level signal (High).

Furthermore, the first switching element SW1 and the second switching element SW2 electrically disconnect the first wire W1 and the second wire W2 from the inverter circuit 220a, for example, in a case of a low-level signal (Low). Contrarily, the first switching element SW1 and the second switching element SW2 electrically connect the first wire W1 and the second wire W2 to the inverter circuit 220b side, for example, in a case of a low-level signal (Low).

More specifically, the inverter circuit 220a includes resistors R1 and R2, a first transistor T11, and a third transistor T12. The first transistor T11 is, for example, an n-type MOS transistor, and the third transistor T12 is, for example, a p-type MOS transistor.

The first transistor T11 and the third transistor T12 are connected in series at a node n2. Furthermore, the power supply line of the potential VDD is connected to the source of the first transistor T11, and the power supply line of the potential Vss is connected to the source of the third transistor T12. The potential Vss is, for example, 0 volts.

The first switching element SW1 is connected to the node n1. Furthermore, the node n1 is connected to the gates of the first transistor T11 and the third transistor T12, and one end of the resistor R1. The other end of the resistor R1 is connected to a power Supply line of the potential VDD. Note that the potential VDD supplied to the node n1 according to the present embodiment corresponds to a first refresh potential.

The second switching element SW2 is connected to the node n2. Furthermore, one end of the resistor R2 is connected to the node n2. The other end of the resistor R2 is supplied with a negative potential V2. Note that the negative potential V2 supplied to the node n2 according to the present embodiment corresponds to a second refresh potential.

As described above, the inverter circuit 220b has a configuration equivalent to that of the inverter circuit 220a. That is, the inverter circuit 220b includes resistors R3, R4, a second transistor T21, and a fourth transistor T22. The resistor R3 corresponds to the resistor R1, the resistor R4 corresponds to the resistor R2, the second transistor T21 corresponds to the first transistor T11, and the fourth transistor T22 corresponds to the third transistor T12. Furthermore, the nodes n3, n4 correspond to the nodes n1, n2, respectively. The first transistor T11 and the second transistor T21 have equivalent input and output characteristics, and the third transistor T12 and the fourth transistor T22 have equivalent input and output characteristics. Since the inverter circuit 220b has a configuration equivalent to that of the inverter circuit 220a, the detailed description of the connection relationship of the inverter circuit 220b will be omitted. Note that the drains of the first transistor T11 and the second transistor T21 according to the present embodiment each correspond to one end, and the sources each correspond to the other end.

### Operation of Electronic Circuit 220

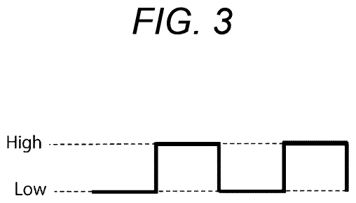

FIG. 3 is a diagram illustrating an example of control signals input to the first switching element SW1 and the second switching element SW2. The horizontal axis represents time. The control signals include periodically changing high-level signals (High) and low-level signals (Low). The synchronization signal TS is supplied to the first switching element SW1 via the first wire W1.

As can be seen from these, clock signals are alternately supplied to the inverter circuit 220a and the inverter circuit 220b in accordance with the cycles of the high-level signal (High) and the low-level signal (Low) of the control signal. Then, the inverter circuit 220a and the inverter circuit 220b alternately invert and amplify the clock signals, and generate the vertical clock signals VCK. That is, in a case where one of the inverter circuit 220a and the inverter circuit 220b executes the following normal drive, the other executes the following refresh drive. Hereinafter, the normal drive and the refresh drive will be described using the inverter circuit 220a as an example, but the normal drive and the refresh drive of the inverter circuit 220b are also similar to those of the inverter circuit 220a.

### Normal Drive

During the period in which the clock signal is supplied to the inverter circuit 220a, the gates of the first transistor T11 and the third transistor T12 are electrically connected to the first wire W1, and the drain of the first transistor T11 and the drain of the third transistor T12 are electrically connected to the second wire W2. With this arrangement, a clock signal is supplied to the gates of the first transistor T11 and the third transistor T12, and the first transistor T11 and the third transistor T12 execute normal drive.

When the clock signal is in a low-level period, the first transistor T11 goes into a non-conductive state, and the third transistor T12 goes into a conductive state. Therefore, the potential VDD is output to the node n2. At this time, a potential VDD, for example, 15.5 volts is applied to the drain of the first transistor T11, and a potential Vss, for example, 0 volts is applied to the source. as described above, in the low-level period of the clock signal, the potential between the source and the drain of the first transistor T11 is high on the drain side.

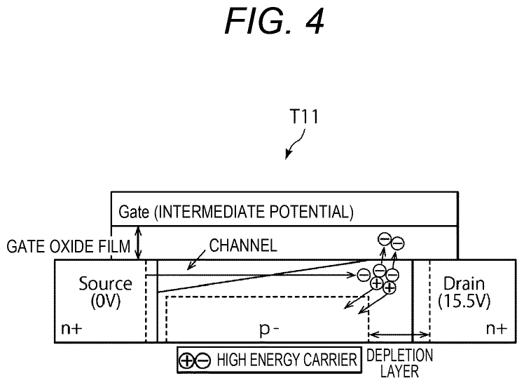

FIG. 4 is a diagram schematically illustrating a state of the first transistor T11 in which the clock signal is in the low-level period. As illustrated in FIG. 4, in a case where the drain side has a high potential, carriers are accelerated by the electric field in the direction along the channel, and carriers having high energy are injected into the gate oxide film beyond the energy barrier at the Si—SiO2 interface. This phenomenon is referred to as a drain avalanche hot carrier (hereinafter referred to as DAHC). That is, in the DAHC, as illustrated in FIG. 4, channel electrons accelerated by obtaining high energy from the horizontal direction in the vicinity of the drain perform collision ionization or avalanche multiplication with Si atoms to generate electron-hole pairs. This shows a phenomenon in which the electrons and holes become hot carriers and are injected into the gate oxide film.

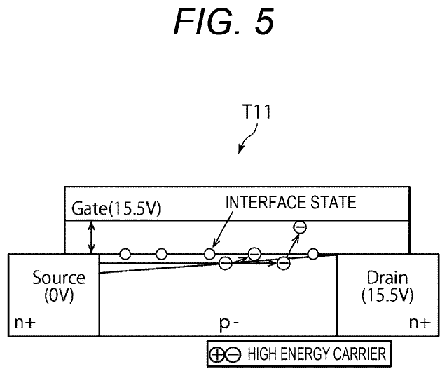

FIG. 5 is a diagram schematically illustrating the CHE of the first transistor T11 in which the clock signal is in the low-level period. As illustrated in FIG. 5, carriers in the channel obtain high energy from the drain electric field in the channel horizontal direction, and generated hot carriers are injected into the gate oxide film or the interface state beyond the energy barrier at the Si—SiO2 interface. This phenomenon is referred to as channel hot electron (hereinafter referred to as CHE). As described above, the first transistor T11 in which the lock signal is in the low-level period is degraded mainly by the DAHC and the CHE.

### Refresh Drive

During a period in which the clock signal is not supplied to the inverter circuit 220a, the gates of the first transistor T11 and the third transistor T12 are electrically disconnected from the first wire W1, and the drain of the first transistor T11 and the drain of the third transistor T12 are electrically disconnected from the second wire W2. Therefore, the potential VDD, for example, 15.5 volts is constantly applied to the gates of the first transistor T11 and the third transistor T12, and the negative potential V2 is constantly applied to the drain of the first transistor T11 and the drain of the third transistor T12. As described above, in the period in which the clock signal is not applied, the potential between the source and the drain of the first transistor T11 is high on the source side. That is, the potential between the source and the drain of the first transistor T11 is inverted from the normal drive potential. That is, the source and the drain of the first transistor T11 are replaced in a pseudo manner. Therefore, a reverse bias is applied so as to simulate switching of the source and the drain of the transistor T11, and hot carriers trapped in the gate oxide film and the interface state are refreshed, so that degradation is prevented. That is, in the refresh drive, a reverse bias simulating source-drain switching is applied to the first transistor T11, and the hot carriers are refreshed. With this arrangement, the normal drive and the refresh drive are alternately performed, and degradation is prevented.

As described above, the second transistor T21 of the inverter circuit 220b is also refreshed similarly to the first transistor T11. That is, the second transistor T21 performs the refresh drive in a period in which the first transistor T11 performs the normal drive. Contrarily, in a period in which the first transistor T11 performs the refresh drive, the second transistor T21 performs the normal drive. Note that the case where the first transistor T11 and the second transistor T21 are n-type MOS transistors has been described, but the present invention is not limited thereto. For example, the first transistor T11 and the second transistor T21 may be P-type MOS transistors. In this case, for example, the second wire is electrically connected with the source of either of the first transistor T11 and the second transistor T21 in a switchable manner. With this arrangement, also in a case where the first transistor T11 and the second transistor T21 are P-type MOS transistors, the potential difference between the source and the drain of each of the first transistor T11 and the second transistor T21 is inverted between the case where a gate of either of the first transistor T11 and the second transistor T21 is electrically connected to the first wire W1 and the corresponding drain is electrically connected to the second wire W2 and the case where the gate and the drain are each electrically disconnected from a corresponding one of the wires, whereby refresh drive and normal drive can be performed, and degradation of the first transistor T11 and the second transistor T21 is prevented.

As can be seen from these, these refresh drives make it possible to improve robustness against variations in performance of the first transistor T11 and the second transistor T21. This makes it possible to narrow the transistor size and the wire width, and contribute to narrowing the frame. In addition, the timing deviation of the vertical clock signal leads to image quality degradation such as light resistance unevenness, image burn-in, a subsequent bright spot, surface roughness, and flicker in the display device 1. Improving robustness against variations in performance of the first transistor T11 and the second transistor T21 can prevent the timing deviation of the vertical clock signal, and can prevent image quality degradation in the display device 1.

As described above, according to the present embodiment, the potential difference between the source and the drain of each of the first transistor T11 and the second transistor T21 is inverted between the case where a gate of either of the first transistor T11 and the second transistor T21 is electrically connected to the first wire W1 and the corresponding drain is electrically connected to the second wire W2 and the case where the gate and the drain are each electrically disconnected from a corresponding one of the wires. This makes it possible to alternately perform normal drives and refresh drives of the first transistor T11 and the second transistor T21, and prevents degradation of the first transistor T11 and the second transistor T21.

### Second Embodiment

A display device 1 according to a second embodiment is different from the display device 1 according to the first embodiment in that the potential VDD is applied to the nodes n1 and n3 via switching elements, and the negative potential V2 is applied to the nodes n2 and n4 via switching elements. Hereinafter, differences from the display device 1 according to the first embodiment will be described.

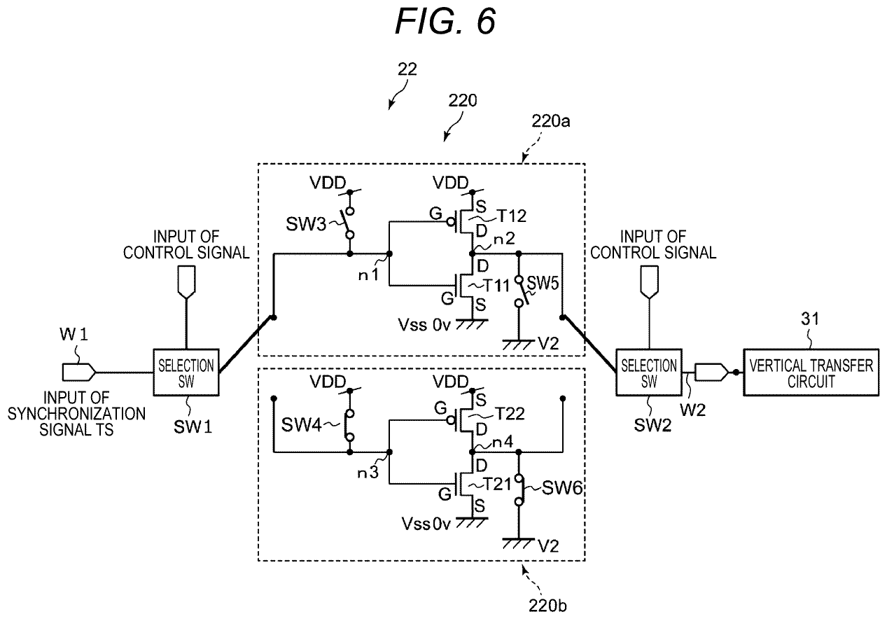

FIG. 6 is a diagram illustrating a configuration example of an electronic circuit 220 according to the second embodiment. As illustrated in FIG. 6, the third switching element SW3 is different from the electronic circuit 220 according to the first embodiment in electrically connecting or disconnecting the power supply line of the potential VDD and the node n1. Similarly, the fourth switching element SW4 is different from the electronic circuit 220 according to the first embodiment in electrically connecting or disconnecting the power Supply line of the potential VDD and the node n5. In addition, the fifth switching element SW5 is different from the electronic circuit 220 according to the first embodiment in electrically connecting or disconnecting the negative potential V2 and the node n2. Similarly, the fifth switching element SW6 is different from the electronic circuit 220 according to the first embodiment in electrically connecting or disconnecting the negative potential V2 and the node n4.

The switching elements SW3 to SW6 are electrically connected or disconnected in synchronization with the first switching element SW1 and the second switching element SW2. That is, as illustrated in FIG. 6, in a case where the first switching element SW1 and the second switching element SW2 are electrically connected to the inverter circuit 220a side, the third switching element SW3 and the fifth switching element SW5 are disconnected, and the fourth switching element SW4 and the sixth switching element SW6 are connected.

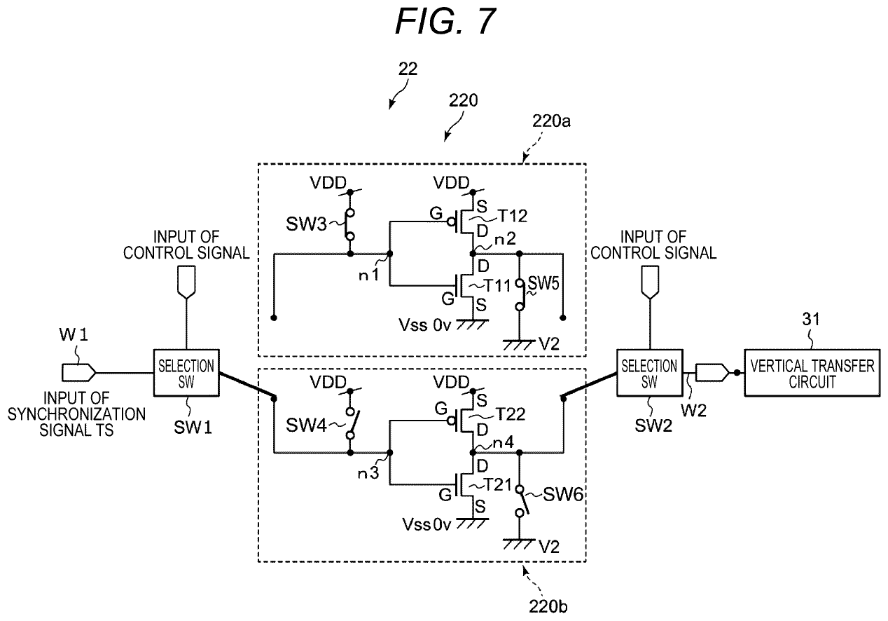

FIG. 7 is a diagram illustrating a configuration example of the electronic circuit 220 in which the first switching element SW1 and the second switching element SW2 are electrically connected to the inverter circuit 220b side. As illustrated in FIG. 7, in a case where the first switching element SW1 and the second switching element SW2 are electrically connected to the inverter circuit 220b side, the third switching element SW3 and the fifth switching element SW5 are connected, and the fourth switching element SW4 and the sixth switching element SW6 are disconnected.

This makes it possible to electrically disconnect the power supply line of the potential VDD from the negative potential V2 for refresh during normal drive, in addition to the effect of the electronic circuit 220 according to the first embodiment.

### Third Embodiment

A display device 1 according to a third embodiment is different from the display device 1 according to the first embodiment in including a charge pump circuit that supplies a negative potential V2. Hereinafter, differences from the display device 1 according to the first embodiment will be described.

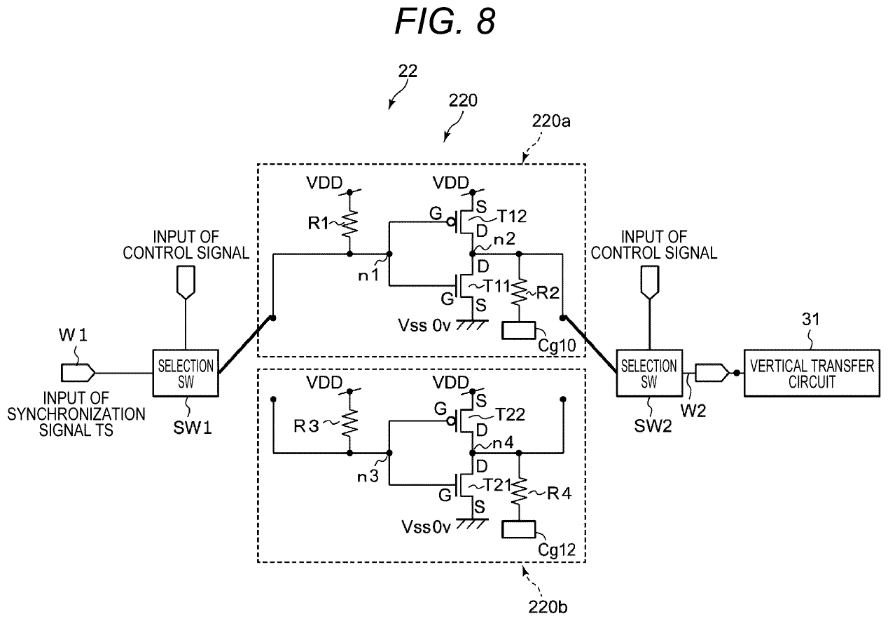

FIG. 8 is a diagram illustrating a configuration example of an electronic circuit according to the third embodiment. As illustrated in FIG. 8, charge pump circuits Cg10 and Cg12 that supply the negative potential V2 are provided.

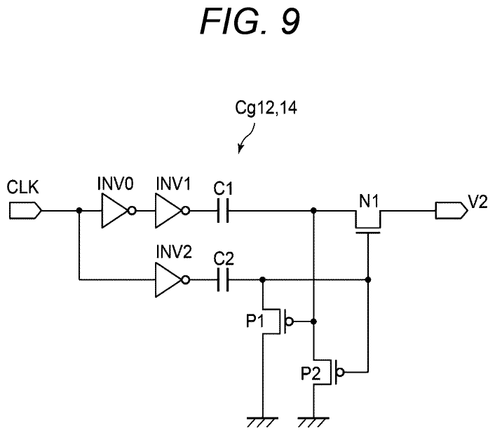

FIG. 9 is a diagram illustrating a configuration example of the charge pump circuits Cg10 and Cg12. As illustrated in FIG. 9, the charge pump circuits Cg10 and Cg12 each include a plurality of inverters INV0 to INV2, a plurality of capacitors C1 and C2, an n-type MOS transistor N1, and a plurality of p-type MOS transistors P1 and P2.

The inverters INV0, INV1 and the capacitor Cl are connected in series between the CLK terminal and one end of the transistor N1. In addition, the inverter INV2 and the capacitor C2 are connected in series between the CLK terminal and the gate of the transistor N1. Furthermore, one end of the transistor P1 is connected to the gate of the transistor N1, the other end thereof is connected to the ground, and the gate thereof is connected to one end of the transistor P2. One end of the transistor P2 is further connected to one end of the transistor N1, the other end of the transistor P2 is connected to the ground, and the gate is connected to the gate of the transistor N1. The charge pump circuits Cg10 and Cg12 generate the negative potential V2 using a clock signal that is the synchronization signal TS.

With this arrangement, in addition to the effect of the electronic circuit 220 according to the first embodiment, the charge pump circuits Cg10 and Cg12 can generate the negative potential V2 using the clock signal that is the synchronization signal TS.

### Fourth Embodiment

A display device 1 according to a fourth embodiment is different from the display device 1 according to the first embodiment in including a first power supply Ps20 that applies a variable potential to the node n1 and a second power supply Ps21 that applies a variable potential to the node n2. Hereinafter, differences from the display device 1 according to the first embodiment will be described.

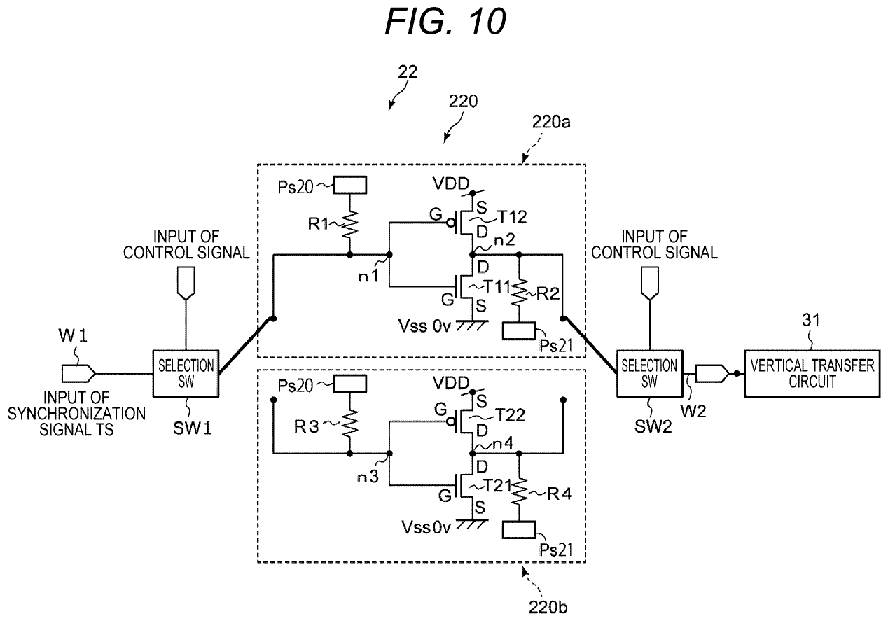

FIG. 10 is a diagram illustrating a configuration example of an electronic circuit according to the third embodiment. As illustrated in FIG. 10, a first power supply Ps20 that applies a variable potential to the node n1 and a second power supply Ps21 that applies a variable potential to the node n2 are provided.

### Refresh of First Transistor T11 and Second Transistor T21

In a case where refresh drive of each of the first transistor T11 and the second transistor T21 is executed, the first power supply Ps20 outputs the potential VDD, and the second power supply Ps21 outputs the negative potential V2. This, similarly to the first embodiment, makes it possible to execute refresh drive of the first transistor T11 and the second transistor T21.

### Refresh of Third Transistor T12 and Fourth Transistor T22

In a case where refresh drive of each of the third transistor T12 and the fourth transistor T22 is executed, the first power supply Ps20 outputs the negative potential VDD, and the second power supply Ps21 outputs the potential VDD+ (absolute value of the negative potential V2). This makes it possible to execute refresh drive of the third transistor T12 and the fourth transistor T22. Note that the output potential of the first power supply Ps20 corresponds to a first refresh potential, and the output potential of the second power supply Ps21 corresponds to a second refresh potential. In addition, in a case where refresh drives of the third transistor T12 and the fourth transistor T22 are executed, the third transistor T12 and the fourth transistor T22 according to the present embodiment correspond to the first transistor and the second transistor, respectively. In addition, the drain of each the third transistor T12 and the fourth transistor T22 according to the present embodiment correspond to one end, and the source thereof corresponds to the other end.

With this arrangement, in addition to the effect of the electronic circuit 220 according to the first embodiment, refresh drive of each of the third transistor T12 and the fourth transistor T22 is also possible.

Note that the present technology may have the following configurations.
(1)

An electronic circuit including:
a first transistor;
a second transistor; and
a first switching element that electrically connects a gate of one of the first transistor and the second transistor, with a first wire, in a switchable manner,
in which one end of the one of the first transistor and the second transistor is electrically connectable to a second wire different from the first wire, and
a potential difference between the one end and another end of the first transistor is inverted between a case where the gate of the first transistor is electrically connected to the first wire and a case where the gate of the first transistor is not electrically connected to the first wire.
(2)

The electronic circuit according to (1), in which a potential difference between the one end and another end of the second transistor is inverted between a case where the gate of the first transistor is electrically connected to the first wire and a case where the gate of the first transistor is not electrically connected to the first wire.
(3)

The electronic circuit according to (2), further including a second switching element that electrically connects the one end of either of the first transistor and the second transistor, with the second wire, in a switchable manner.
(4)

The electronic circuit according to (3), in which a first refresh potential is applied to gates of the first transistor and the second transistor, and a second refresh potential different from the first refresh potential is applied to one of the one ends of the first transistor and the second transistor.
(5)

The electronic circuit according to (4), further including:
a third switching element that switches between an applied state and a non-applied state of the first refresh potential to the gate of the first transistor;
a fourth switching element that switches between an applied state and a non-applied state of the first refresh potential to the gate of the second transistor;
a fifth switching element that switches between an applied state and a non-applied state of the second refresh potential to the one end of the first transistor; and
a sixth switching element that switches between an applied state and a non-applied state of the second refresh potential to the one end of the second transistor.
(6)

The electronic circuit according to (5), in which
in a case where the gate of the first transistor is connected to the first wire, the third switching element and the fifth switching element are brought into a disconnected state, and
in a case where the gate of the first transistor is not connected to the first wire, the third switching element and the fifth switching element are brought into a connected state.
(7)

The electronic circuit according to (6), further including:
a third transistor connected in series to the first transistor; and
a fourth transistor connected in series to the second transistor.
(8)

The electronic circuit according to (7), in which in a case where the first transistor and the second transistor are n-type MOS transistors, the third transistor and the fourth transistor are p-type MOS transistors.
(9)

The electronic circuit according to (8), in which in a case where the first transistor and the second transistor are n-type MOS transistors, the first refresh potential is higher than the second refresh potential.
(10)

The electronic circuit according to (7), in which in a case where the first transistor and the second transistor are p-type MOS transistors, the third transistor and the fourth transistor are n-type MOS transistors.
(11)

The electronic circuit according to (8), in which in a case where the first transistor and the second transistor are p-type MOS transistors, the first refresh potential is lower than the second refresh potential.
(12)

The electronic circuit according to (7), in which the first wire is alternately supplied with a high-level signal and a low-level signal.

The electronic circuit according to (12), in which
the first refresh potential is applied to a gate of the first transistor via a first resistor,
the first refresh potential is applied to a gate of the second transistor via a second resistor,
the second refresh potential is applied to the one end of the first transistor via a third resistor, and
the second refresh potential is applied to the one end of the second transistor via a fourth resistor.
(14)

The electronic circuit according to (1), in which the first transistor and the second transistor have equivalent input and output characteristics.
(15)

The electronic circuit according to (7), in which the third transistor and the fourth transistor have equivalent input and output characteristics.
(16)

The electronic circuit according to (13), in which the second refresh potential is generated by a charge pump circuit.
(17)

The electronic circuit according to (13), in which the first refresh potential is generated by a first power supply having a variable potential.
(18)

The electronic circuit according to (13), in which the second refresh potential is generated by a second power supply having a variable potential.
(19)

A Display Device Including:
a plurality of scanning lines extending in a row direction, a plurality of signal lines extending in a column direction, and pixel array units each provided at a corresponding one of points where the scanning lines and the signal lines intersect with each other, the pixel array units each including a plurality of pixels;
a driver that causes each of the pixel array units to generate image light based on a video signal; and
a controller that executes control of drive in the driver,
in which the driver includes a vertical drive circuit connected to the plurality of scanning lines and a horizontal drive circuit connected to the plurality of signal lines,
the controller includes an electronic circuit that generates a vertical clock signal and supplies the vertical clock signal to the vertical drive circuit,
the electronic circuit includes:
a first transistor;
a second transistor; and
a first switching element that electrically connects a gate of one of the first transistor and the second transistor, with a first wire through which a clock signal is transmitted, in a switchable manner,
one end of the one of the first transistor and the second transistor is electrically connectable to a second wire that transmits the vertical clock signal, and
a potential difference between the one end and another end of the first transistor is inverted between a case where the gate of the first transistor is electrically connected to the first wire and a case where the gate of the first transistor is not electrically connected to the first wire.
(20)

The display device according to (19), in which each of the pixels includes a liquid crystal cell, a pixel transistor that samples a voltage of a corresponding one of the signal lines based on a signal input from a corresponding one of the scanning lines and writes the voltage in the liquid crystal cell, and a capacitive element connected in parallel to the liquid crystal cell.

Aspects of the present disclosure are not limited to the individual embodiments described above, but include various modifications that may be conceived by those skilled in the art, and the effects of the present disclosure are not limited to the contents described above. That is, various additions, modifications, and partial deletions may be made without departing from the conceptual idea and spirit of the present disclosure derived from the matters defined in the claims and equivalents thereof.

### REFERENCE SIGNS LIST

1 Display device
10 Pixel array unit
20 Controller
30 Liquid crystal driver
220 Electronic circuit
Cg10 Charge pump circuit
Cg12 Charge pump circuit
Ps20 First power supply
Ps21 Second power supply
SW1 First switching element
SW2 Second switching element
SW3 Third switching element
SW4 Fourth switching element
SW5 Fifth switching element
SW6 Sixth switching element
T11 First transistor
T12 Third transistor
T21 Second transistor
T22 Fourth transistor

1. An electronic circuit comprising:
a first transistor;
a second transistor; and
a first switching element that electrically connects a gate of one of the first transistor and the second transistor, with a first wire, in a switchable manner,
wherein one end of the one of the first transistor and the second transistor is electrically connectable to a second wire different from the first wire, and
a potential difference between the one end and another end of the first transistor is inverted between a case where the gate of the first transistor is electrically connected to the first wire and a case where the gate of the first transistor is not electrically connected to the first wire.

2. The electronic circuit according to claim 1, wherein a potential difference between the one end and another end of the second transistor is inverted between a case where the gate of the first transistor is electrically connected to the first wire and a case where the gate of the first transistor is not electrically connected to the first wire.

3. The electronic circuit according to claim 2, further comprising a second switching element that electrically connects the one end of either of the first transistor and the second transistor, with the second wire, in a switchable manner.

4. The electronic circuit according to claim 3, wherein a first refresh potential is applied to gates of the first transistor and the second transistor, and a second refresh potential different from the first refresh potential is applied to one of the one ends of the first transistor and the second transistor.

5. The electronic circuit according to claim 4, further comprising:
a third switching element that switches between an applied state and a non-applied state of the first refresh potential to the gate of the first transistor;
a fourth switching element that switches between an applied state and a non-applied state of the first refresh potential to the gate of the second transistor;
a fifth switching element that switches between an applied state and a non-applied state of the second refresh potential to the one end of the first transistor; and
a sixth switching element that switches between an applied state and a non-applied state of the second refresh potential to the one end of the second transistor.

6. The electronic circuit according to claim 5, wherein
in a case where the gate of the first transistor is connected to the first wire, the third switching element and the fifth switching element are brought into a disconnected state, and
in a case where the gate of the first transistor is not connected to the first wire, the third switching element and the fifth switching element are brought into a connected state.

7. The electronic circuit according to claim 6, further comprising:
a third transistor connected in series to the first transistor; and
a fourth transistor connected in series to the second transistor.

8. The electronic circuit according to claim 7, wherein in a case where the first transistor and the second transistor are n-type MOS transistors, the third transistor and the fourth transistor are p-type MOS transistors.

9. The electronic circuit according to claim 8, wherein in a case where the first transistor and the second transistor are n-type MOS transistors, the first refresh potential is higher than the second refresh potential.

10. The electronic circuit according to claim 7, wherein in a case where the first transistor and the second transistor are p-type MOS transistors, the third transistor and the fourth transistor are n-type MOS transistors.

11. The electronic circuit according to claim 8, wherein in a case where the first transistor and the second transistor are p-type MOS transistors, the first refresh potential is lower than the second refresh potential.

12. The electronic circuit according to claim 7, wherein the first wire is alternately supplied with a high-level signal and a low-level signal.

13. The electronic circuit according to claim 12, wherein
the first refresh potential is applied to a gate of the first transistor via a first resistor,
the first refresh potential is applied to a gate of the second transistor via a second resistor,
the second refresh potential is applied to the one end of the first transistor via a third resistor, and
the second refresh potential is applied to the one end of the second transistor via a fourth resistor.

14. The electronic circuit according to claim 1, wherein the first transistor and the second transistor have equivalent input and output characteristics.

15. The electronic circuit according to claim 7, wherein the third transistor and the fourth transistor have equivalent input and output characteristics.

16. The electronic circuit according to claim 13, wherein the second refresh potential is generated by a charge pump circuit.

17. The electronic circuit according to claim 13, wherein the first refresh potential is generated by a first power supply having a variable potential.

18. The electronic circuit according to claim 13, wherein the second refresh potential is generated by a second power supply having a variable potential.

19. A display device comprising:
a plurality of scanning lines extending in a row direction, a plurality of signal lines extending in a column direction, and pixel array units each provided at a corresponding one of points where the scanning lines and the signal lines intersect with each other, the pixel array units each including a plurality of pixels;
a driver that causes each of the pixel array units to generate image light based on a video signal; and
a controller that executes control of drive in the driver,
wherein the driver includes a vertical drive circuit connected to the plurality of scanning lines and a horizontal drive circuit connected to the plurality of signal lines,
the controller includes an electronic circuit that generates a vertical clock signal and supplies the vertical clock signal to the vertical drive circuit,
the electronic circuit includes:
a first transistor;
a second transistor; and
a first switching element that electrically connects a gate of one of the first transistor and the second transistor, with a first wire through which a clock signal is transmitted, in a switchable manner,
one end of the one of the first transistor and the second transistor is electrically connectable to a second wire that transmits the vertical clock signal, and
a potential difference between the one end and another end of the first transistor is inverted between a case where the gate of the first transistor is electrically connected to the first wire and a case where the gate of the first transistor is not electrically connected to the first wire.

20. The display device according to claim 19, wherein each of the pixels includes a liquid crystal cell, a pixel transistor that samples a voltage of a corresponding one of the signal lines based on a signal input from a corresponding one of the scanning lines and writes the voltage in the liquid crystal cell, and a capacitive element connected in parallel to the liquid crystal cell.
